(19) United States
(12) Patent Application Publication
(10) Pub. No.: US 2026/0357425 A1
(43) Pub. Date: Nov. 12, 2026

(54) FILM-FORMING METHOD AND FILM-FORMING APPARATUS

(71) Applicant: Tokyo Electron Limited, Tokyo (JP)

(72) Inventors: Ren MUKOUYAMA, Iwate (JP); Masato KOAKUTSU, Iwate (JP); Hiroki MIURA, Iwate (JP)

(21) Appl. No.: 19/659,772

(22) Filed: Apr. 27, 2026

(30) Foreign Application Priority Data
May 9, 2025 (JP) 2025-078365

(51) Int. Cl. C23C 16/455; C23C 16/04; C23C 16/40; C23C 16/52; H10P 14/60; H10P 14/692

(52) U.S. Cl. CPC C23C 16/45527; C23C 16/045; C23C 16/401; C23C 16/45544; C23C 16/52; H10P 14/6339; H10P 14/69215

(57) ABSTRACT

A film-forming method of forming a silicon oxide film using a silicon raw material and an oxidizing agent includes supplying the silicon raw material to a substrate having a recess such that the silicon raw material is adsorbed onto the recess; supplying an inhibitor to the substrate that inhibits oxidation caused by the oxidizing agent such that the inhibitor is selectively adhered to an upper portion of the recess; oxidizing the silicon raw material adsorbed onto a lower portion of the recess by supplying the oxidizing agent to the substrate while inhibiting the oxidation of the silicon raw material using the inhibitor adhering to the upper portion of the recess; and repeatedly performing, in sequence, the adsorption of the silicon raw material, the adhesion of the inhibitor, and the oxidization of the silicon raw material.

### CROSS-REFERENCE TO RELATED APPLICATIONS

This application is based upon and claims priority to Japanese Patent Application No. 2025-078365, filed on May 9, 2025, the entire contents of which are incorporated herein by reference.

### BACKGROUND

### 1. Field of the Invention

The present disclosure relates to a film-forming method and a film-forming apparatus.

### 2. Description of the Related Art

Japanese Patent Application Publication No. 2018-010950 discloses that, when filling a silicon nitride film into a recess formed in a substrate, a chlorine-containing gas is physically adsorbed onto a predetermined region from the uppermost portion of the recess to a predetermined depth of the recess, thereby forming a non-adsorptive site for a silicon-containing gas in the predetermined region.

### SUMMARY

A film-forming method according to an aspect of the present disclosure forms a silicon oxide film using a silicon raw material and an oxidizing agent. The film-forming method includes: supplying the silicon raw material to a substrate having a recess such that the silicon raw material is adsorbed onto the recess; supplying an inhibitor to the substrate that inhibits oxidation caused by the oxidizing agent such that the inhibitor is selectively adhered to an upper portion of the recess; oxidizing the silicon raw material adsorbed onto a lower portion of the recess by supplying the oxidizing agent to the substrate while inhibiting the oxidation of the silicon raw material using the inhibitor adhering to the upper portion of the recess; and repeatedly performing the adsorption of the silicon raw material, the adhesion of the inhibitor, and the oxidization of the silicon raw material such that the adsorption of the silicon raw material is followed by the adhesion of the inhibitor, and the adhesion of the inhibitor is followed by the oxidization of the silicon raw material.

### BRIEF DESCRIPTION OF THE DRAWINGS

FIG. 1 is a schematic cross-sectional diagram of a film-forming apparatus according to an embodiment of the present disclosure.

FIG. 2 is a schematic plan diagram of the film-forming apparatus of FIG. 1.

FIG. 3 is a cross-sectional diagram (1) of a film-forming method according to an embodiment of the present disclosure.

FIG. 4 is a cross-sectional diagram (2) of the film-forming method according to the embodiment.

FIG. 5 is a diagram illustrating a relationship between conditions for supplying an inhibitor to a substrate and a region to which a chlorine gas is adhered.

FIG. 6 is a graph illustrating a relationship between a flow rate of the chlorine gas and a film thickness of a silicon oxide film.

FIG. 7 is a graph illustrating a relationship between a rotation speed of a rotary table and the film thickness of the silicon oxide film.

FIG. 8 is a graph illustrating a relationship between an internal pressure of a processing chamber and the film thickness of the silicon oxide film.

### DETAILED DESCRIPTION OF THE DISCLOSURE

The present disclosure provides a technique of forming a silicon oxide film to be thicker in a lower portion of a recess than in an upper portion of the recess.

Hereinafter, non-limiting exemplary embodiments of the present disclosure will be described with reference to the drawings. In the drawings, the same or corresponding members or components are denoted by the same or corresponding reference signs, and duplicate descriptions thereof will be omitted.

### Film-Forming Apparatus

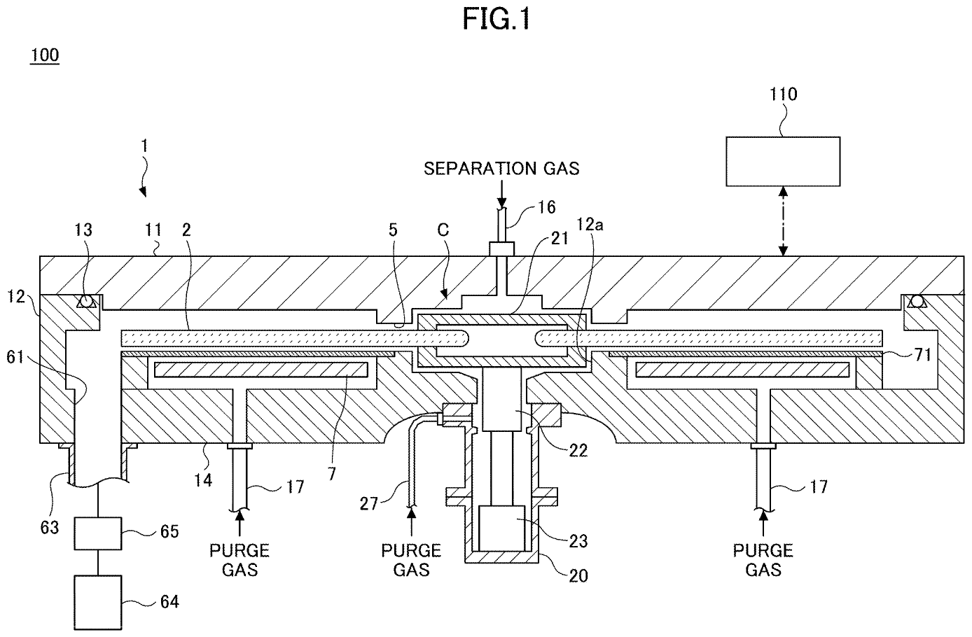

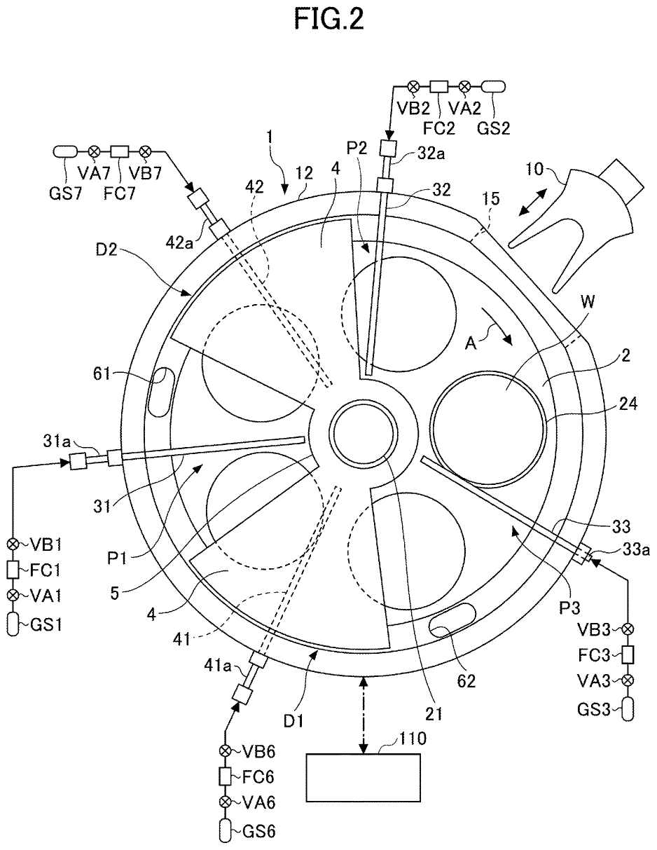

FIG. 1 is a schematic cross-sectional diagram of a film-forming apparatus 100 according to an embodiment of the present disclosure. FIG. 2 is a schematic plan diagram of the film-forming apparatus 100 of FIG. 1. In FIG. 2, illustration of a top plate 11 is omitted for the sake of convenience of description.

The film-forming apparatus 100 includes a substantially cylindrical processing chamber 1, and a rotary table 2 configured to rotate a substrate W in the processing chamber 1. The substrate W is, for example, a semiconductor wafer. The film-forming apparatus 100 includes a controller 110 configured to control the components of the film-forming apparatus 100.

The processing chamber 1 includes therein a processing section configured to store a plurality of substrates W and form a silicon oxide film over each substrate W. The processing chamber 1 includes the top plate 11, a chamber body 12, and a sealing member 13. The top plate 11 is detachably provided to the chamber body 12. The sealing member 13 has an annular shape, and is provided on the upper surface of an outer circumferential wall of the chamber body 12. Thus, the top plate 11 is airtightly fixed to the chamber body 12. The sealing member 13 is, for example, an O-ring.

A separation gas supply tube 16 configured to supply a separation gas, such as a nitrogen (N₂) gas, an argon (Ar) gas, or the like, is connected to the center of the top plate 11. A plurality of purge gas supply tubes 17 configured to supply a purge gas, such as a nitrogen gas, an argon gas, or the like, are connected to a bottom surface 14 of the chamber body 12. The plurality of purge gas supply tubes 17 are provided along the circumferential direction of the bottom surface 14. The bottom surface 14 includes an annular projecting portion 12a at a position near the outer circumferential surface of a core 21 configured to fix the rotary table 2.

The outer circumferential wall of the processing chamber 1 is provided with: a transfer port 15 through which the substrate W is delivered between the rotary table 2 and a transfer arm 10; and a gate valve (not shown) configured to open and close the transfer port 15. The gate valve airtightly seals the processing section of the processing chamber 1 with the transfer port 15 being closed. The rotary table 2 is configured to position a stage 24, on which the substrate W is to be placed, at a position near the transfer port 15, and to transfer the substrate W to and from the transfer arm 10.

The rotary table 2 is housed in the processing chamber 1. The rotary table 2 is fixed to the substantially disk-shaped core 21 at the center of the processing chamber 1. The core 21 is connected to a rotation shaft 22 extending in the vertical direction. The rotation shaft 22 is supported by a driver 23. The driver 23 is configured to rotate the rotary table 2 about a vertical axis (clockwise in FIG. 2) using the rotation shaft 22.

The driver 23 and the lower end of the rotation shaft 22 are housed in a casing 20. The casing 20 is airtightly attached to the bottom surface 14 of the processing chamber 1. A purge gas supply tube 27 configured to supply a purge gas to a lower region of the rotary table 2 is connected to the casing 20.

The rotary table 2 includes, for example, a plurality (five in the illustrated example) of circular stages 24 configured to receive the substrate W having a diameter of 300 millimeters (mm). The plurality of stages 24 are provided at equal intervals along the rotation direction of the rotary table 2. Each stage 24 has an inner diameter that is slightly greater (by about 1 mm or more and about 4 mm or less) than the diameter of the substrate W. The depth of the stage 24 is set to be equal to or greater than the thickness of the substrate W.

The bottom surface of the stage 24 is provided with a plurality (e.g., three) of through-holes (not shown) configured to allow passage of a plurality of raising and lowering pins (not shown). Each raising and lowering pin is provided at a delivery position of the substrate W near the transfer port 15, and is configured to be raised and lowered in an up-down direction by a raising and lowering mechanism (not shown). Each raising and lowering pin is configured to be raised after entry of the transfer arm 10 holding the substrate W to receive the substrate W, and to be lowered after retraction of the transfer arm 10 to place the substrate W on the stage 24. Each raising and lowering pin is configured to raise the substrate W having undergone substrate processing, and to deliver the substrate W to the transfer arm 10 that enters afterwards.

Above the rotary table 2, processing gas nozzles 31, 32, and 33 and separation gas nozzles 41 and 42 are disposed at intervals in the circumferential direction of the processing chamber 1. In the illustrated example, the processing gas nozzle 33, the separation gas nozzle 41, the processing gas nozzle 31, the separation gas nozzle 42, and the processing gas nozzle 32 are disposed sequentially clockwise (the rotation direction indicated by an arrow A in FIG. 2) from the transfer port 15, which will be described below. The processing gas nozzles 31, 32, and 33 and the separation gas nozzles 41 and 42 are formed, for example, of quartz. In the processing gas nozzles 31, 32, and 33 and the separation gas nozzles 41 and 42, their base ends, i.e., gas inlet ports 31a, 32a, 33a, 41a, and 42a are fixed to the outer circumferential wall of the chamber body 12. Thus, the processing gas nozzles 31, 32, and 33 and the separation gas nozzles 41 and 42 are introduced into the processing chamber 1 from the outer circumferential wall of the processing chamber 1, and are attached to extend horizontally with respect to the rotary table 2 along the radial direction of the chamber body 12.

The processing gas nozzle 31 includes a plurality of gas holes (not shown) on the lower surface side (facing the rotary table 2). The processing gas nozzle 31 is connected to a supply source GS1, configured to be charged with a silicon raw material, outside the processing chamber 1. The processing gas nozzle 31 is configured to jet the silicon raw material from the supply source GS1 into a first processing region P1, which is below the processing section, through the gas holes. The flow rate of the silicon raw material from the supply source GS1 is controlled by a flow rate controller FC1. The supply and stop of the silicon raw material from the supply source GS1 into the processing chamber 1 are controlled by valves VA1 and VB1. The silicon raw material is, for example, a tris-dimethylaminosilane (TDMAS) gas. A supply source configured to be charged with another gas, e.g., a dilution gas, such as an argon gas or the like, may be further connected to the processing gas nozzle 31.

The processing gas nozzle 32 includes a plurality of gas holes (not shown) on the lower surface side (facing the rotary table 2). The processing gas nozzle 32 is connected to a supply source GS2, configured to be charged with an inhibitor, outside the processing chamber 1. The processing gas nozzle 32 is configured to jet the inhibitor from the supply source GS2 into a second processing region P2, which is below the processing section, through the gas holes. The flow rate of the inhibitor from the supply source GS2 is controlled by a flow rate controller FC2. The supply and stop of the inhibitor from the supply source GS2 into the processing chamber 1 are controlled by valves VA2 and VB2. The inhibitor is, for example, a chlorine (Cl₂) gas. A supply source configured to be charged with another gas, e.g., a dilution gas, such as an argon gas or the like, may be further connected to the processing gas nozzle 32.

The processing gas nozzle 33 includes a plurality of gas holes (not shown) on the lower surface side (facing the rotary table 2). The processing gas nozzle 33 is connected to a supply source GS3, configured to be charged with an oxidizing agent, outside the processing chamber 1. The processing gas nozzle 33 is configured to jet the oxidizing agent from the supply source GS3 to a third processing region P3, which is below the processing section, through the gas holes. The flow rate of the oxidizing agent from the supply source GS3 is controlled by a flow rate controller FC3. The supply and stop of the oxidizing agent from the supply source GS3 into the processing chamber 1 are controlled by valves VA3 and VB3. The oxidizing agent is, for example, an ozone (O₃) gas or a gas mixture of a hydrogen gas and an oxygen gas. A supply source configured to be charged with another gas, e.g., a dilution gas, such as an argon gas or the like, may be further connected to the processing gas nozzle 33.

The separation gas nozzle 41 forms a separation region D1 that exists between the first processing region P1 and the third processing region P3. The separation gas nozzle 41 includes a plurality of gas holes (not shown) on the lower surface side (facing the rotary table 2). The separation gas nozzle 41 is connected to a supply source GS6 configured to be charged with the separation gas. The separation gas nozzle 41 is configured to jet the separation gas from the supply source GS6 into the separation region D1, which is below the processing section, through the gas holes. The flow rate of the separation gas from the supply source GS6 is controlled by a flow rate controller FC6. The supply and stop of the separation gas from the supply source GS6 into the processing chamber 1 are controlled by valves VA6 and VB6. The separation gas is, for example, an inert gas, such as a nitrogen gas, an argon gas, or the like.

The separation gas nozzle 42 forms a separation region D2 that exists between the first processing region P1 and the second processing region P2. The separation gas nozzle 42 includes a plurality of gas holes (not shown) on the lower surface side (facing the rotary table 2). The separation gas nozzle 42 is connected to a supply source GS7 configured to be charged with the separation gas. The separation gas nozzle 42 is configured to jet the separation gas from the supply source GS7 to the separation region D2, which is below the processing section, through the gas holes. The flow rate of the separation gas from the supply source GS7 is controlled by a flow rate controller FC7. The supply and stop of the separation gas from the supply source GS7 into the processing chamber 1 are controlled by valves VA7 and VB7. The separation gas is, for example, an inert gas, such as a nitrogen gas, an argon gas, or the like.

Substantially fan-shaped projecting portions 4 are provided on the rear surface of the top plate 11 of the processing chamber 1 in the separation regions D1 and D2. The projecting portions 4 project downward from the rear surface of the top plate 11. The projecting portions 4 include radially extending grooves (not shown) at the center in the circumferential direction, and are configured to house the separation gas nozzles 41 and 42 in the grooves.

A projecting portion 5, formed in a substantially annular shape along the circumferential direction, is provided at the center of the lower surface of the top plate 11 to be continuous with the projecting portions 4 closer to a center region C. The lower surface of the projecting portion 5 is formed at the same height as the lower surfaces of the projecting portions 4.

The bottom surface 14 of the processing chamber 1 is provided with a first gas exhaust port 61 and a second gas exhaust port 62. The first gas exhaust port 61 is provided between the processing gas nozzle 31 and the separation region D2. The second gas exhaust port 62 is provided between the processing gas nozzle 33 and the separation region D1. The first gas exhaust port 61 mainly exhausts the silicon raw material and the separation gas, and the second gas exhaust port 62 mainly exhausts the inhibitor, the oxidizing agent, and the separation gas. The first gas exhaust port 61 and the second gas exhaust port 62 are connected to an exhauster 64, such as a vacuum pump or the like, through a gas exhaust tube 63. The gas exhaust tube 63 is provided with a pressure controller 65, such as a butterfly valve or the like.

The film-forming apparatus 100 includes a heater 7 in a space between the rotary table 2 and the bottom surface 14 of the processing chamber 1. The heater 7 is housed in a cover 71 supported by the projecting portion 12a of the chamber body 12. The heater 7 is configured to heat the substrate W on the rotary table 2 to a predetermined temperature.

The controller 110 is an electronic circuit, such as a CPU (Central Processing Unit), an FPGA (Field Programmable Gate Array), an ASIC (Application Specific Integrated Circuit), or the like. The controller 110 is configured to execute various control operations described in the present specification by executing instruction codes stored in a memory or by being designed as a circuit for specific applications.

### Film-Forming Method

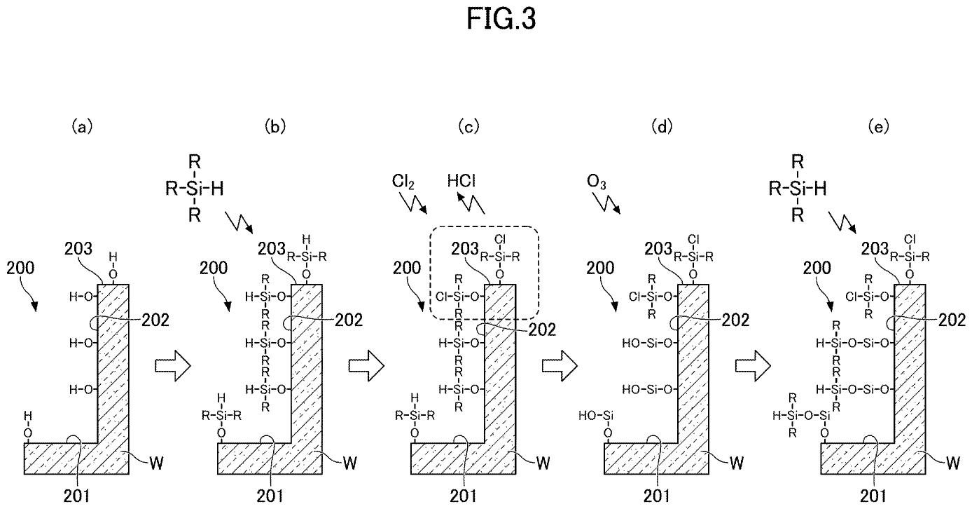

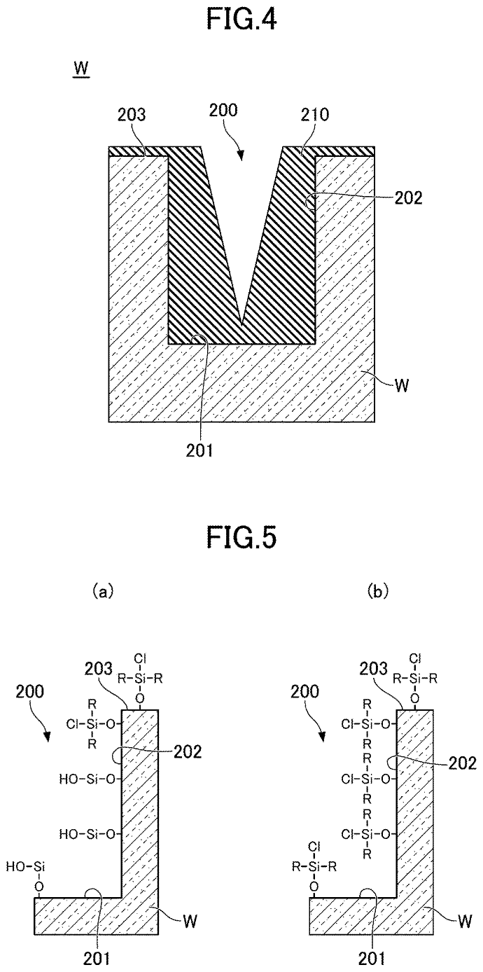

FIGS. 3 and 4 are cross-sectional diagrams of a film-forming method according to an embodiment of the present disclosure. The following description will be made taking, as an example, a case in which a silicon oxide film is formed in a recess 200 formed in the surface of the substrate W in the film-forming apparatus 100 described above. In the embodiment, the silicon raw material is a TDMAS gas, the inhibitor is a chlorine gas, the oxidizing agent is an ozone gas, and the purge gas and the separation gas are each a nitrogen gas. The TDMAS gas includes hydrogen (H) as a first element X1. The chlorine gas includes chlorine (Cl) as a second element X2.

First, the controller 110 controls the film-forming apparatus 100 to place the substrate W on each stage 24 of the rotary table 2 in the processing chamber 1. As illustrated in (a) of FIG. 3, the recess 200, such as a trench, a hole, or the like, is formed in the surface of the substrate W. The recess 200 includes a bottom surface 201, a side surface 202, and a top surface 203. For example, OH groups are formed on the bottom surface 201, the side surface 202, and the top surface 203. The bottom surface 201 and a lower portion of the side surface 202 form a lower portion of the recess 200, and the top surface 203 and an upper portion of the side surface 202 form an upper portion of the recess 200.

Next, the controller 110 controls the valves VA6 and VB6 and the flow rate controller FC6 to supply a nitrogen gas from the separation gas nozzle 41 to the separation region D1. Also, the controller 110 controls the valves VA7 and VB7 and the flow rate controller FC7 to supply a nitrogen gas from the separation gas nozzle 42 to the separation region D2. Also, the controller 110 controls valves (not shown) and a flow rate controller (not shown) to supply a nitrogen gas from the separation gas supply tube 16 and the purge gas supply tubes 17 and 27 into the processing chamber 1. Also, the controller 110 controls the pressure controller 65 such that the internal pressure of the processing chamber 1 reaches a desired pressure. Also, the controller 110 controls the driver 23 to rotate the rotary table 2 clockwise at a desired rotation speed. Also, the controller 110 controls the heater 7 such that the temperature of the substrate W reaches a desired temperature.

Next, the controller 110 controls the valves VA1 and VB1 and the flow rate controller FC1 to supply the TDMAS gas from the processing gas nozzle 31 to the first processing region P1. Thus, in the first processing region P1, the TDMAS gas is adsorbed onto both the upper portion and the lower portion of the recess 200 of the substrate W, as illustrated in (b) of FIG. 3. In (b) of FIG. 3, —NC₂H₆ included in the TDMAS gas is denoted by -R. For example, by adjusting the flow rate of the TDMAS gas, the rotation speed of the rotary table 2, the internal pressure of the processing chamber 1, and the like, it is possible for the TDMAS gas to adsorb to both the upper portion and the lower portion of the recess 200.

The controller 110 controls the valves VA2 and VB2 and the flow rate controller FC2 to supply the chlorine gas from the processing gas nozzle 32 to the second processing region P2. Thus, in the second processing region P2, the chlorine gas is adhered selectively to the upper portion of the recess 200 to form Si—Cl bonds, as illustrated in (c) of FIG. 3. The binding energy of the Si—Cl bond is greater than the binding energy of the Si—H bond. Therefore, the probability of oxidation caused by the ozone gas decreases in the surface where the Si—Cl bonds exist. In other words, the oxidation caused by the ozone gas is inhibited. For example, by adjusting the flow rate of the chlorine gas, the rotation speed of the rotary table 2, the internal pressure of the processing chamber 1, and the like, it is possible for the chlorine gas to adhere selectively to the upper portion of the recess 200.

FIG. 5 is a diagram illustrating a relationship between conditions for supplying the inhibitor to the substrate W and the region to which the chlorine gas is adhered. For example, by decreasing the flow rate of the chlorine gas, increasing the rotation speed of the rotary table 2, or decreasing the internal pressure of the processing chamber 1, the chlorine gas adheres selectively to the upper portion of the recess 200, as illustrated in (a) of FIG. 5. Conversely, by increasing the flow rate of the chlorine gas, decreasing the rotation speed of the rotary table 2, or increasing the internal pressure of the processing chamber 1, the chlorine gas adheres to both the upper portion and the lower portion of the recess 200, as illustrated in (b) of FIG. 5.

The controller 110 controls the valves VA3 and VB3 and the flow rate controller FC3 to supply an ozone gas from the processing gas nozzle 33 to the third processing region P3. Thus, in the third processing region P3, the TDMAS gas adsorbed onto the lower portion of the recess 200 is oxidized while inhibiting the oxidation of the TDMAS gas caused by the chlorine gas adhering to the upper portion of the recess 200, as illustrated in (d) of FIG. 3. In the substrate W moved from the second processing region P2 to the third processing region P3 in accordance with the rotation of the rotary table 2, there are many Si—H bonds in the lower portion of the recess 200, while there are many Si—Cl bonds in the upper portion of the recess 200. The binding energy of the Si—Cl bond is greater than the binding energy of the Si—H bond. Therefore, when an ozone gas is supplied to the substrate W, the TDMAS gas adsorbed onto the lower portion of the recess 200 is more likely to react with the ozone gas than does the TDMAS gas adsorbed onto the upper portion of the recess 200. As a result, the TDMAS gas adsorbed onto the lower portion of the recess 200 is selectively oxidized, thereby forming OH groups selectively in the lower portion of the recess 200.

When the substrate W is moved again from the third processing region P3 to the first processing region P1 in accordance with the rotation of the rotary table 2, the TDMAS gas is adsorbed selectively onto the lower portion of the recess 200 in the first processing region P1, as illustrated in (e) of FIG. 3. In the substrate W moved from the third processing region P3 to the first processing region P1 in accordance with the rotation of the rotary table 2, there are many OH groups on the surface of the lower portion of the recess 200, while there are many Si—Cl bonds on the surface of the lower portion of the recess 200. The TDMAS gas tends to be adsorbed to the OH groups. Therefore, the TDMAS gas is adsorbed selectively onto the lower portion of the recess 200.

The controller 110 controls the driver 23 to continue the rotation of the rotary table 2. Thus, with the temperature of the substrate W being maintained at a desired temperature, the adsorption of the TDMAS gas onto the surface of the recess 200, the adhesion of the chlorine gas, and the oxidation of the TDMAS gas are repeatedly performed such that the adsorption of the TDMAS gas is followed by the adhesion of the chlorine gas, and the adhesion of the chlorine gas is followed by the oxidation of the TDMAS gas. As a result, as illustrated in FIG. 4, a silicon oxide film 210 having a desired film thickness is formed over the surface of the recess 200. Here, the chlorine gas inhibits the oxidation of the TDMAS gas caused by the ozone gas in the upper portion of the recess 200. Therefore, the silicon oxide film 210 can be formed to be thicker in the lower portion of the recess 200 than in the upper portion of the recess 200.

When the film thickness of the silicon oxide film 210 reaches a desired thickness, the controller 110 controls the valves VA1 to VA3, the valves VB1 to VB3, and the flow rate controllers FC1 to FC3 to stop the supply of the gases from the processing gas nozzles 31, 32, and 33. Also, the controller 110 controls the valves VA6 and VA7, the valves VB6 and VB7, and the flow rate controllers FC6 and FC7 to stop the supply of the nitrogen gas from the separation gas nozzles 41 and 42. Also, the controller 110 controls the valves and the flow rate controller to stop the supply of the nitrogen gas from the separation gas supply tube 16 and the purge gas supply tubes 17 and 27.

Next, the controller 110 controls the film-forming apparatus 100 to transfer the substrate W, placed on each stage 24 of the rotary table 2 in the processing chamber 1, out of the processing chamber 1.

### First Experiment

In a first experiment, the influence of the timing of supplying the inhibitor to the substrate W on the effect of inhibiting the formation of the silicon oxide film 210 was evaluated.

In the first experiment, a film thickness TA1 of the silicon oxide film 210, formed by repeatedly performing, in sequence, the adsorption of the silicon raw material onto the substrate W and the oxidation of the silicon raw material, without performing the adhesion of the inhibitor to the substrate W, was measured. Also, a film thickness TA2 of the silicon oxide film 210, formed by repeatedly performing, in sequence, the adsorption of the silicon raw material onto the substrate W, the adhesion of the inhibitor to the substrate W, and the oxidation of the silicon raw material, was measured. A film thickness reduction percentage [%] defined by {(TA1−TA2)/TA1}×100 was calculated.

For comparison, a film thickness TB1 of the silicon oxide film 210, formed by repeatedly performing, in sequence, the adsorption of the silicon raw material onto the substrate W and the oxidation of the silicon raw material, without performing the adhesion of the inhibitor to the substrate W, was measured. Also, a film thickness TB2 of the silicon oxide film 210, formed by repeatedly performing, in sequence, the adsorption of the silicon raw material onto the substrate W, the oxidation of the silicon raw material, and the adhesion of the inhibitor to the substrate W, was measured. A film thickness reduction percentage [%] defined by {(TB1−TB2)/TB1}×100 was calculated.

In the first experiment, the substrate W including a silicon oxide film formed over the surface was used, the TDMAS gas was used as a silicon raw material, a chlorine gas diluted with a nitrogen gas was used as an inhibitor, and a gas mixture of a hydrogen gas and an oxygen gas was used as an oxidizing agent. In the first experiment, the temperature of the substrate W was set to 600 degrees Celsius (°C), the internal pressure of the processing chamber 1 was set to 6.7 Torr, and the rotation speed of the rotary table 2 was set to 120 rpm. In the first experiment, the number of repetitions of a cycle including the adsorption of the silicon raw material onto the substrate W and the oxidation of the silicon raw material was set to 800 times.

In the first experiment, the film thickness reduction percentage was used as an index of the inhibitory effect of the inhibitor on the oxidation of the silicon raw material. The larger the value of the film thickness reduction percentage, the higher the inhibitory effect of the inhibitor on the formation of the silicon oxide film 210.

As a result of the experiment, when repeatedly performing, in sequence, the adsorption of the silicon raw material onto the substrate W, the adhesion of the inhibitor to the substrate W, and the oxidation of the silicon raw material, the film thickness reduction percentage was 7.9%. This result indicates the inhibitory effect of the inhibitor on the formation of the silicon oxide film 210 when repeatedly performing, in sequence, the adsorption of the silicon raw material onto the substrate W, the adhesion of the inhibitor to the substrate W, and the oxidation of the silicon raw material.

When repeatedly performing, in sequence, the adsorption of the silicon raw material onto the substrate W, the oxidation of the silicon raw material, and the adhesion of the inhibitor to the substrate W, the film thickness reduction percentage was −0.2%. This result indicates no inhibitory effect of the inhibitor on the formation of the silicon oxide film 210 when repeatedly performing, in sequence, the adsorption of the silicon raw material onto the substrate W, the oxidation of the silicon raw material, and the adhesion of the inhibitor to the substrate W.

### Second Experiment

In a second experiment, the influence of conditions for supplying the chlorine gas to the substrate W on a film thickness distribution of the silicon oxide film 210 in a depth direction in the recess 200 was evaluated.

In the second experiment, the adsorption of the silicon raw material onto the substrate W, the adhesion of the inhibitor to the substrate W, and the oxidation of the silicon raw material were repeatedly performed in sequence, thereby forming the silicon oxide film 210 in the recess 200 of the substrate W, and measuring the film thickness distribution of the silicon oxide film 210 in the depth direction in the recess 200.

In the second experiment, base conditions for forming the silicon oxide film 210 were as follows.

### (Base Conditions)

Silicon raw material: TDMAS gas (300 sccm)
Inhibitor: chlorine gas/nitrogen gas (200 sccm/1,000 sccm)
Oxidizing agent: ozone gas (6,000 sccm)
Rotation speed of the rotary table 2:30 rpm
Internal pressure of the processing chamber 1:6.7 Torr
Temperature of the substrate W: 760 °C

In the second experiment, the flow rate of the chlorine gas when supplying the chlorine gas to the substrate W, the rotation speed of the rotary table 2, and the internal pressure of the processing chamber 1 were changed from the corresponding base conditions. The flow rate of the chlorine gas was set to 50 sccm, 100 sccm, 150 sccm, or 200 sccm. The rotation speed of the rotary table 2 was set to 30 rpm, 60 rpm, or 120 rpm. The internal pressure of the processing chamber 1 was set to 2.0 Torr, 4.5 Torr, 6.7 Torr, or 9.0 Torr.

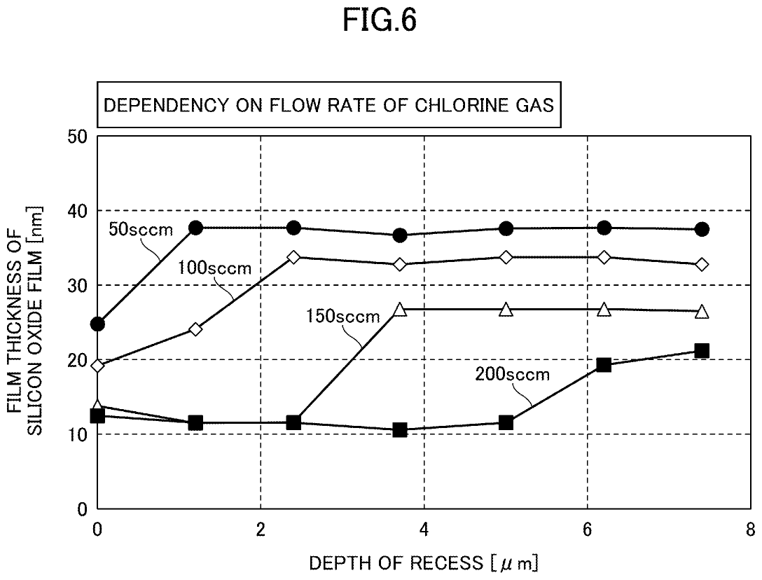

FIG. 6 is a graph illustrating a relationship between the flow rate of the chlorine gas and the film thickness of the silicon oxide film 210. In FIG. 6, the horizontal axis indicates a depth [μm] of the recess 200, and the vertical axis indicates a film thickness [nm] of the silicon oxide film. In FIG. 6, circular marks, rhombic marks, triangular marks, and square marks respectively indicate the results obtained when the flow rate of the chlorine gas was 50 sccm, 100 sccm, 150 sccm, and 200 sccm.

As illustrated in FIG. 6, by adjusting the flow rate of the chlorine gas, it is possible to control the cross-sectional shape of the silicon oxide film 210 formed in the recess 200. Specifically, as the flow rate of the chlorine gas decreases, a cross-sectional shape is formed in which the film thickness of the silicon oxide film 210 is reduced in a narrow range at a shallow position of the recess 200. This is likely because, as the flow rate of the chlorine gas decreases, the chlorine gas adheres selectively to the shallow position of the recess 200, resulting in that the oxidation caused by the ozone gas is readily inhibited at the shallow position of the recess 200.

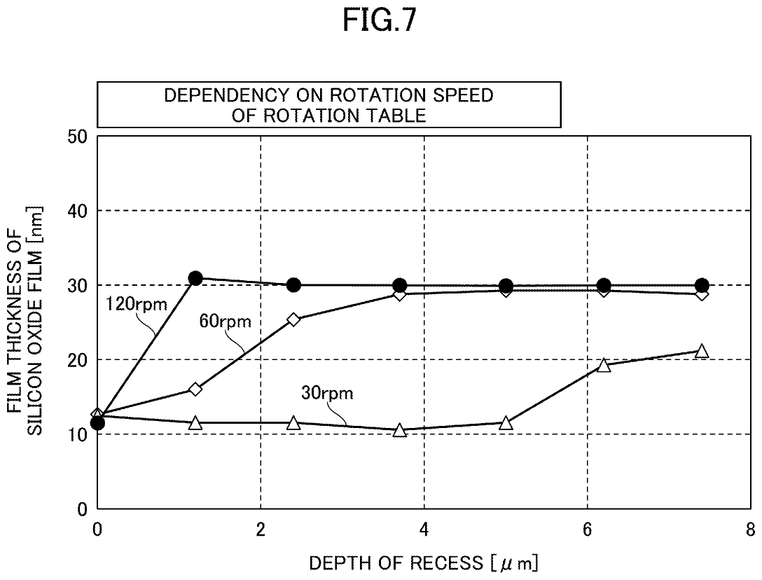

FIG. 7 is a graph illustrating a relationship between the rotation speed of the rotary table 2 and the film thickness of the silicon oxide film 210. In FIG. 7, the horizontal axis indicates a depth [μm] of the recess 200, and the vertical axis indicates a film thickness [nm] of the silicon oxide film. In FIG. 7, circular marks, rhombic marks, and triangular marks respectively indicate the results obtained when the rotation speed of the rotary table 2 was 120 rpm, 60 rpm, and 30 rpm.

As illustrated in FIG. 7, by adjusting the rotation speed of the rotary table 2, it is possible to control the cross-sectional shape of the silicon oxide film 210 formed in the recess 200. Specifically, as the rotation speed of the rotary table 2 increases, a cross-sectional shape is formed in which the film thickness of the silicon oxide film 210 is reduced in a narrow range at a shallow position of the recess 200. This is likely because, as the rotation speed of the rotary table 2 increases, the chlorine gas adheres selectively to the shallow position of the recess 200, resulting in that the oxidation caused by the ozone gas is readily inhibited at the shallow position of the recess 200.

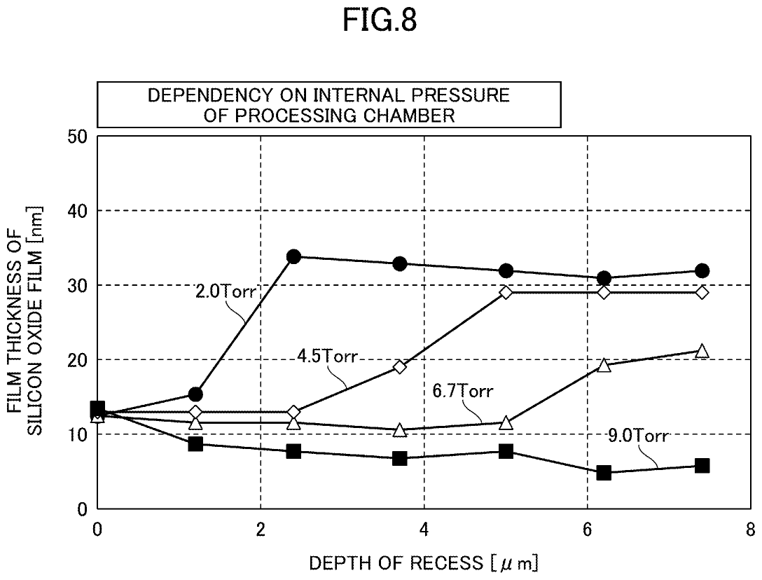

FIG. 8 is a graph illustrating a relationship between the internal pressure of the processing chamber 1 and the film thickness of the silicon oxide film 210. In FIG. 8, the horizontal axis indicates a depth [μm] of the recess 200, and the vertical axis indicates a film thickness [nm] of the silicon oxide film. In FIG. 8, circular marks, rhombic marks, triangular marks, and square marks respectively indicate the results obtained when the internal pressure of the processing chamber 1 was 2.0 Torr, 4.5 Torr, 6.7 Torr, and 9.0 Torr.

As illustrated in FIG. 8, by adjusting the internal pressure of the processing chamber 1, it is possible to control the cross-sectional shape of the silicon oxide film 210 formed in the recess 200. Specifically, as the internal pressure of the processing chamber 1 decreases, a cross-sectional shape is formed in which the film thickness of the silicon oxide film 210 is reduced in a narrow range at a shallow position of the recess 200. This is likely because, as the internal pressure of the processing chamber 1 decreases, the chlorine gas adheres selectively to the shallow position of the recess 200, resulting in that the oxidation caused by the ozone gas is readily inhibited at the shallow position of the recess 200.

The embodiments disclosed herein are exemplary in all respects and are not restrictive. In the above-described embodiments, omissions, substitutions, or modifications may be possible in various forms without departing from the scope and intent of claims recited.

The above embodiments have been described using the case in which the silicon raw material is a TDMAS gas. However, the present disclosure is not limited to this. The silicon raw material may be a dichlorosilane (DCS) gas, a hexachlorodisilane (HCD) gas, a diisopropylaminosilane (DIPAS) gas, a tris-dimethylaminosilane (TDMAS) gas, a bis(tert-butylamino)silane (BTBAS) gas, or any combination thereof.

The above embodiments have been described using the case in which the inhibitor is a chlorine gas. However, the present disclosure is not limited to this. The inhibitor may be a material that contains the second element X2 having a binding energy to silicon greater than the first element X1 having the lowest binding energy to silicon among the elements binding to silicon contained in the silicon raw material, and that does not gasify when adhered to the silicon raw material. In this case, it is possible to form an Si-X2 bond that is not readily cleaved by the oxidizing agent compared to an Si-X1 bond. In the surface where the second element X2 exists, the probability of oxidation caused by the oxidizing agent is reduced. In other words, oxidation caused by the oxidizing agent is inhibited. The binding energy to silicon is, in ascending order, an Si—H bond, an Si—P bond, an Si—Cl bond, an Si—N bond, an Si—C bond, an Si—F bond, an Si—S bond, and an Si—O bond. For example, when the first element X1 is hydrogen (H), the second element X2 may be an element having a binding energy to silicon greater than the binding energy of hydrogen to silicon. Specifically, the second element X2 may be phosphorus (P), chlorine (Cl), nitrogen (N), carbon (C), fluorine (F), or sulfur(S). Examples of phosphorus-containing materials include phosphorus-containing gases, such as a phosphine gas and the like. Examples of chlorine-containing materials include chlorine-containing gases, such as a chlorine gas, a hydrogen chloride gas, and the like. Examples of nitrogen-containing materials include nitrogen-containing gases, such as an ammonia gas and the like. Examples of carbon-containing materials include carbon-containing gases, such as an ethylene gas, a methane gas, and the like. Examples of fluorine-containing materials include fluorine-containing gases, such as a methane tetrafluoride gas and the like. Examples of sulfur-containing materials include sulfur-containing gases, such as a hydrogen sulfide gas and the like. The binding energy of the second element X2 to silicon may be lower than the binding energy of oxygen (O) to silicon.

The above embodiments have been described using the case in which the oxidizing agent is an ozone gas or a gas mixture of a hydrogen gas and an oxygen gas. However, the present disclosure is not limited to this. The oxidizing agent may be a hydrogen peroxide gas. Also, a plasma may be generated from the oxidizing agent.

According to the present disclosure, it is possible to form a silicon oxide film to be thicker in a lower portion of a recess than in an upper portion of the recess.

What is claimed is:

1. A film-forming method of forming a silicon oxide film using a silicon raw material and an oxidizing agent, the film-forming method comprising:
supplying the silicon raw material to a substrate having a recess such that the silicon raw material is adsorbed onto the recess;
supplying an inhibitor to the substrate that inhibits oxidation caused by the oxidizing agent such that the inhibitor is selectively adhered to an upper portion of the recess;
oxidizing the silicon raw material adsorbed onto a lower portion of the recess by supplying the oxidizing agent to the substrate while inhibiting the oxidation of the silicon raw material using the inhibitor adhering to the upper portion of the recess; and
repeatedly performing the adsorption of the silicon raw material, the adhesion of the inhibitor, and the oxidization of the silicon raw material such that the adsorption of the silicon raw material is followed by the adhesion of the inhibitor, and the adhesion of the inhibitor is followed by the oxidization of the silicon raw material.

2. The film-forming method according to claim 1, wherein
the inhibitor includes a material that includes a second element having a binding energy to silicon greater than a first element having a lowest binding energy to the silicon among elements that bind to the silicon included in the silicon raw material.

3. The film-forming method according to claim 2, wherein
the first element is hydrogen, and
the second element is phosphorus, chlorine, nitrogen, fluorine, or sulfur.

4. The film-forming method according to claim 1, wherein
the inhibitor includes a chlorine-containing gas.

5. The film-forming method according to claim 1, wherein
the inhibitor includes an ozone gas.

6. The film-forming method according to claim 1, wherein
the adsorption of the silicon raw material, the adhesion of the inhibitor, and the oxidization of the silicon raw material are performed with a temperature of the substrate being maintained at a same temperature.

7. The film-forming method according to claim 1, wherein
the adsorption of the silicon raw material, the adhesion of the inhibitor, and the oxidization of the silicon raw material are performed by placing the substrate on a rotary table provided in a processing chamber along a circumferential direction of the rotary table, and causing the placed substrate to pass through a first processing region, a second processing region, and a third processing region in accordance with rotation of the rotary table, and wherein
the first processing region, the second processing region, and the third processing region are spaced apart from each other along a rotation direction of the rotary table,
the first processing region is configured to perform the adsorption of the silicon raw material,
the second processing region is configured to perform the adhesion of the inhibitor, and
the third processing region is configured to perform the oxidization of the silicon raw material.

8. The film-forming method according to claim 7, wherein
the adhesion of the inhibitor includes controlling a cross-sectional shape of the silicon oxide film formed in the recess, by adjusting at least one of a flow rate of the inhibitor, a rotation speed of the rotary table, or an internal pressure of the processing chamber.

9. A film-forming apparatus configured to form a silicon oxide film using a silicon raw material and an oxidizing agent, the film-forming apparatus comprising:
a controller including circuitry configured to control the film-forming apparatus to perform:
supplying the silicon raw material to a substrate having a recess such that the silicon raw material is adsorbed onto the recess;
supplying an inhibitor to the substrate that inhibits oxidation caused by the oxidizing agent such that the inhibitor is selectively adhered to an upper portion of the recess;
oxidizing the silicon raw material adsorbed onto a lower portion of the recess by supplying the oxidizing agent to the substrate while inhibiting the oxidation of the silicon raw material using the inhibitor adhering to the upper portion of the recess; and
repeatedly performing the adsorption of the silicon raw material, the adhesion of the inhibitor, and the oxidization of the silicon raw material such that the adsorption of the silicon raw material is followed by the adhesion of the inhibitor, and the adhesion of the inhibitor is followed by the oxidization of the silicon raw material.
